(19) United States
(12) Patent Application Publication
(10) Pub. No.: US 2009/0294958 A1
(43) Pub. Date: Dec. 3, 2009

(54) WAFER LEVEL REDISTRIBUTION USING CIRCUIT PRINTING TECHNOLOGY

(75) Inventor: Kunzhong (Kevin) Hu, Newport Beach, CA (US)

Correspondence Address: FIALA & WEAVER, P.L.L.C.;C/O CPA GLOBAL, P.O. BOX 52050, MINNEAPOLIS, MN, 55402, US

(73) Assignee: BROADCOM CORPORATION, Irvine, CA (US)

(21) Appl. No.: 12/130,584

(22) Filed: May 30, 2008

(51) Int. Cl. H01L 23/52; H01L 21/00

(52) U.S. Cl. 257/737; 438/113; 257/E23.141; 257/E21.001

(57) ABSTRACT

Methods, systems, and apparatuses for wafer-level integrated circuit (IC) packages are described. A wafer has a surface defined by a plurality of integrated circuit regions Each integrated circuit region has a passivation layer and a plurality of terminals on the surface of the wafer accessible through openings in the passivation layer. An ink jet printer is configured to print a plurality of routing interconnects on the surface of a wafer in the form of an ink. The ink jet printer is configured to print the plurality of routing interconnects such that each routing interconnect has a first portion in contact with a respective terminal of the plurality of terminals and has a second portion that extends over the passivation layer. Bump interconnects are attached to the routing interconnects. The wafer may be singulated to create a plurality of wafer-level integrated circuits.

### BACKGROUND OF THE INVENTION

1. Field of the Invention

The present invention relates to integrated circuit packaging technology, and more particularly to wafer-level ball grid array packages.

2. Background Art

Integrated circuit (IC) chips or dies are typically interfaced with other circuits using a package that can be attached to a printed circuit board (PCB). One such type of IC die package is a ball grid array (BGA) package. BGA packages provide for smaller footprints than many other package solutions available today. A BGA package has an array of solder ball pads located on a bottom external surface of a package substrate. Solder balls are attached to the solder ball pads. The solder balls are reflowed to attach the package to the PCB.

An advanced type of BGA package is a wafer-level BGA package. Wafer-level BGA packages have several names in industry, including wafer level chip scale packages (WLCSP), among others. In a wafer-level BGA package, the solder bumps/balls are mounted directly to I/O pads/terminals of the IC chip when the IC chip has not yet been singulated from its fabrication wafer. Wafer-level BGA packages can therefore be made very small, with high pin out, relative to other IC package types including traditional BGA packages.

On some IC dies, the I/O terminals/pads are not positioned in desired locations for solder bumps/balls. For example, some IC dies may be designed for use in wirebond IC packages. For IC dies used in wirebond packages, the I/O terminals are generally positioned along the peripheral edges of the IC die. In this manner, bond wires may be conveniently connected between the I/O terminals and locations on a surface of a substrate or leadframe of the wirebond package. However, it may be desired to use dies designed for use in wirebond packages as wafer-level packages. Because the I/O pads of an IC die configured for a wirebond package are typically too close together to have solder bumps formed directly on them, redistribution layers may be formed on the IC die to provide redistributed access to the I/O pads. A redistribution layer is a type of routing formed on an IC die between an I/O pad and another region of the die at which the solder bump may be formed.

Conventional processes for forming wafer-level redistribution layers are very costly and time consuming. For example, redistribution layers may be formed by sputtering or electroplating processes, which are expensive and time consuming. Furthermore, expensive masks are required. Still further, one or more polymer layers are typically formed on the wafer to enable the sputtering or electroplating processes for forming the redistribution layers to be performed on the wafer. Thus, what is needed are less expensive and time consuming processes for forming redistribution layers.

### BRIEF SUMMARY OF THE INVENTION

Methods, systems, and apparatuses for wafer-level integrated circuit (IC) packages are described. Routing interconnects are printed onto a wafer to provide redistributed access to the I/O pads of integrated circuits on the wafer. Printing of the routing interconnects onto the wafer enables a less expensive and less timing consuming process for forming redistribution layers to be performed.

In one example implementation, a method for forming integrated circuit (IC) packages is provided. A wafer is received that has a surface defined by a plurality of integrated circuit regions. Each integrated circuit region has a passivation layer and a plurality of terminals accessible through openings in the passivation layer. A plurality of routing interconnects are printed on the surface of the wafer in the form of an ink such that each routing interconnect has a first portion in contact with a respective terminal and has a second portion that extends over the passivation layer. A plurality of bump interconnects are formed on the plurality of routing interconnects. The wafer may be singulated to create a plurality of wafer-level integrated circuit packages that each has a plurality of routing interconnects.

In an example implementation, an ink jet printer is configured to print the plurality of routing interconnects on the surface of a wafer. The ink jet printer is configured to print the plurality of routing interconnects such that each routing interconnect has the first portion in contact with the respective terminal of the plurality of terminals and has the second portion that extends over the passivation layer.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a flowchart providing example steps for performing wafer-level package processing.

FIG. 2 shows a plan view of an example wafer.

FIG. 3 shows a cross-sectional view of wafer, showing an example integrated circuit region in the wafer.

FIG. 4 shows a flowchart providing example steps for performing back-end processing of a wafer.

FIG. 5 shows a flowchart providing example steps for performing front-end processing of a wafer with redistribution layers and under bump metallization layers.

FIG. 6 shows a view of an integrated circuit region of a wafer.

FIGS. 7, 8, and 10 show cross-sectional side views of a portion of an integrated circuit region of a wafer at different times during a redistribution layer fabrication process.

FIG. 9 shows a view of a surface of a portion of an integrated circuit region of a wafer.

FIG. 11 shows a cross-sectional view of an integrated circuit region, according to an example embodiment of the present invention.

FIG. 12 shows a surface view of the integrated circuit region shown in FIG. 11, according to an example embodiment of the present invention.

FIG. 13 shows an integrated circuit region, according to an example embodiment of the present invention.

FIG. 14 shows a flowchart for front-end processing of integrated circuit packages, according to an embodiment of the present invention.

FIG. 15 shows an example integrated circuit package fabrication system, according to an embodiment of the present invention.

FIG. 16 shows the integrated circuit region of FIG. 13 prior to application of bump interconnects, according to an example embodiment of the present invention.

FIGS. 17 and 18 show side cross-sectional and bottom views of an example wafer-level integrated circuit package, according to an example embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Examples of Wafer-Level Processing

“Wafer-level packaging” is an integrated circuit packaging technology where all packaging-related interconnects are applied while the integrated circuit dies or chips are still in wafer form. After the packaging-related interconnects are applied, the wafer is tested and singulated into individual devices, and may be sent to customers for their use.

Thus, individual packaging of discrete devices is not required. The size of the final package is essentially the size of the corresponding chip, resulting in a very small package solution. Wafer-level packaging is becoming increasingly popular as the demand for increased functionality in small form-factor devices increases. These applications include mobile devices such as cell phones, PDAs, and MP3 players, for example.

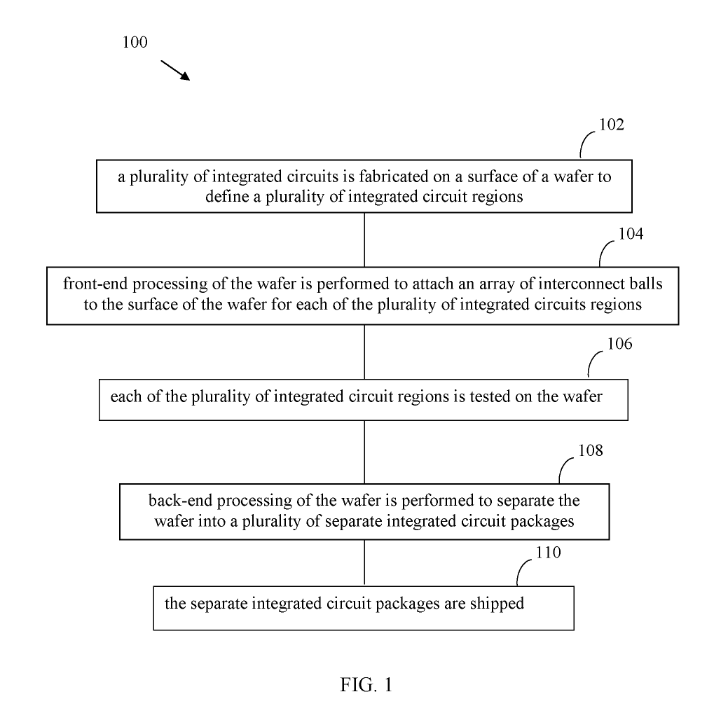

FIG. 1 shows a flowchart 100 providing example steps for performing wafer-level package processing. Flowchart 100 begins with step 102. In step 102, a plurality of integrated circuits is fabricated on a surface of a wafer to define a plurality of integrated circuit regions. For example, FIG. 2 shows a plan view of a wafer 200. Wafer 200 may be silicon, gallium arsenide, or other wafer type. As shown in FIG. 2, wafer 200 has a surface 202 defined by a plurality of integrated circuit regions (shown as small rectangles in FIG. 2). Each integrated circuit region is configured to be packaged separately into a separate wafer-level ball grid array package according to the process of flowchart 100.

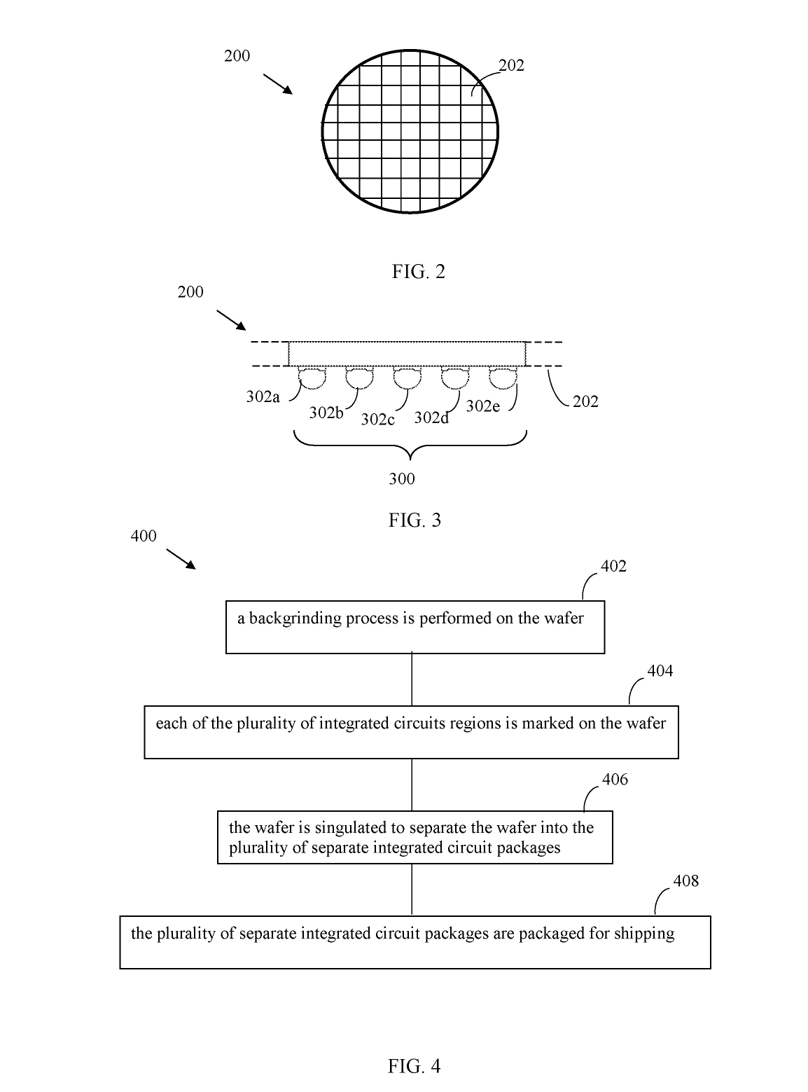

In step 104, front-end processing of the wafer is performed to attach an array of interconnect balls to the surface of the wafer for each of the plurality of integrated circuits regions. A critical part of wafer-level packaging is the front-end process of step 104. In step 104, appropriate interconnects and packaging materials are applied to the wafer. For example, FIG. 3 shows a cross-sectional side view of wafer 200, highlighting an integrated circuit region 300. As shown in FIG. 3, integrated circuit region 300 has a plurality of interconnect balls 302a-302e attached thereto on surface 202. Interconnect balls 302a-302e may be solder, other metal, combination of metals/alloy, etc. Interconnect balls 302 are used to interface the package resulting from integrated circuit region 300 with an external device, such as a PCB.

In step 106, each of the plurality of integrated circuits regions is tested on the wafer. For example, each integrated circuit region can be interfaced with probes at interconnect balls 302 to provide ground, power, and test input signals, and to receive test output signals.

In step 108, back-end processing of the wafer is performed to separate the wafer into a plurality of separate integrated circuit packages. Example back-end processing is described below.

In step 110, the separate integrated circuit packages are shipped. For example, the separate integrated circuit packages may be shipped to a warehouse, to customers, to a site for assembly into devices, to a site for further processing, etc.

FIG. 4 shows a flowchart 400 providing example steps for performing back-end processing of a wafer, according to step 108 of flowchart 100. Not all steps of flowchart 400 are necessarily performed in all back-end processing applications. The steps of flowchart 400 need not necessarily be performed in the order shown. Flowchart 400 begins with step 402. In step 402, a backgrinding process is performed on the wafer. For example, the backgrinding process may be performed on wafer 200 to reduce a thickness of wafer 200 to a desired amount.

In step 404, each of the plurality of integrated circuits regions is marked on the wafer. For example, each integrated circuit region may be marked with information that may be used to identify the particular type of ball grid array package, such as manufacturer identifying information, part number information, etc. For instance, integrated circuit region 300 may be marked on the side of wafer 200 that is opposite surface 202 shown in FIG. 3.

In step 406, the wafer is singulated to separate the wafer into the plurality of separate integrated circuit packages. Wafer 200 may be singulated/diced in any appropriate manner to physically separate the integrated circuit regions from each other, as would be known to persons skilled in the relevant art(s).

In step 408, the plurality of separate integrated circuit packages are packaged for shipping. For example, the separated integrated circuit packages may be placed in one or more tapes/reels, individual packaging, or other transport mechanism, for shipping packages to customers, etc.

The front-end process of step 104 is critical to forming a reliable IC package. Aspects of the front-end process of step 104 may be performed differently, depending on factors such as the way the wafer is fabricated, etc. In some cases, the front-end process needs to deposit metal layers to provide circuitry/routing from chip terminals to external package terminals. For example, some IC dies may be designed for use in wirebond IC packages. In a wirebond package, the I/O pads are generally positioned along the peripheral edges of the IC die. In this manner, bond wires may be conveniently connected between the I/O pads and locations on a surface of a substrate of the wirebond package. However, it may be desired to use dies designed for use in wirebond IC packages as wafer-level packages. Because the I/O pads of an IC die configured for a wirebond package are typically too close together to have solder bumps formed on them, redistribution layers (RDLs) may be formed on the IC die to provide redistributed access to the I/O pads. A redistribution layer is a type of routing formed on an IC die between an I/O pad and another region of the die at which the solder bump may be formed.

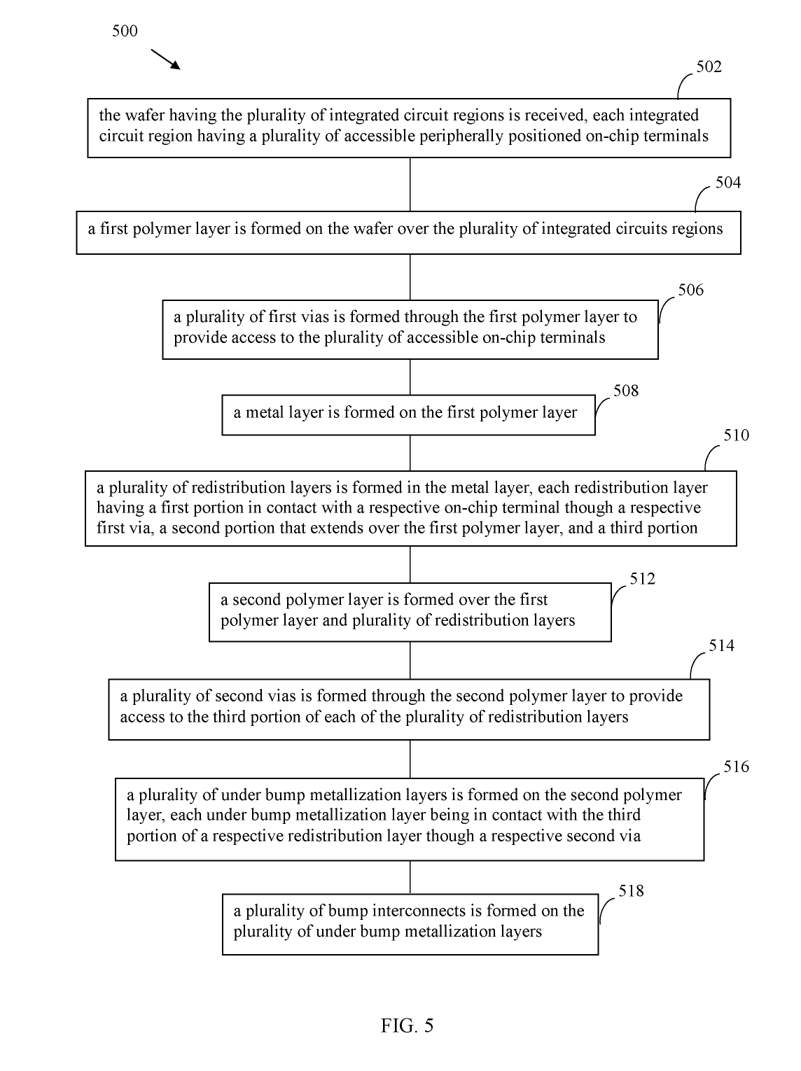

Conventional processes for forming wafer-level redistribution layers are very costly and time consuming. There are several approaches to the “front-end” process of step 104. In one example approach, “redistribution layers” (RDLs), under bump metallization layers (UBMs), and bump interconnects (along with multiple polymer layers) are used to route electrical signals from chip terminals to external (e.g., PCB) terminals. An example of this approach is described below with respect to flowchart 500 of FIG. 5. FIG. 5 shows a flowchart 500 providing example steps for performing front-end processing of a wafer with redistribution layers. Flowchart 500 is described as follows.

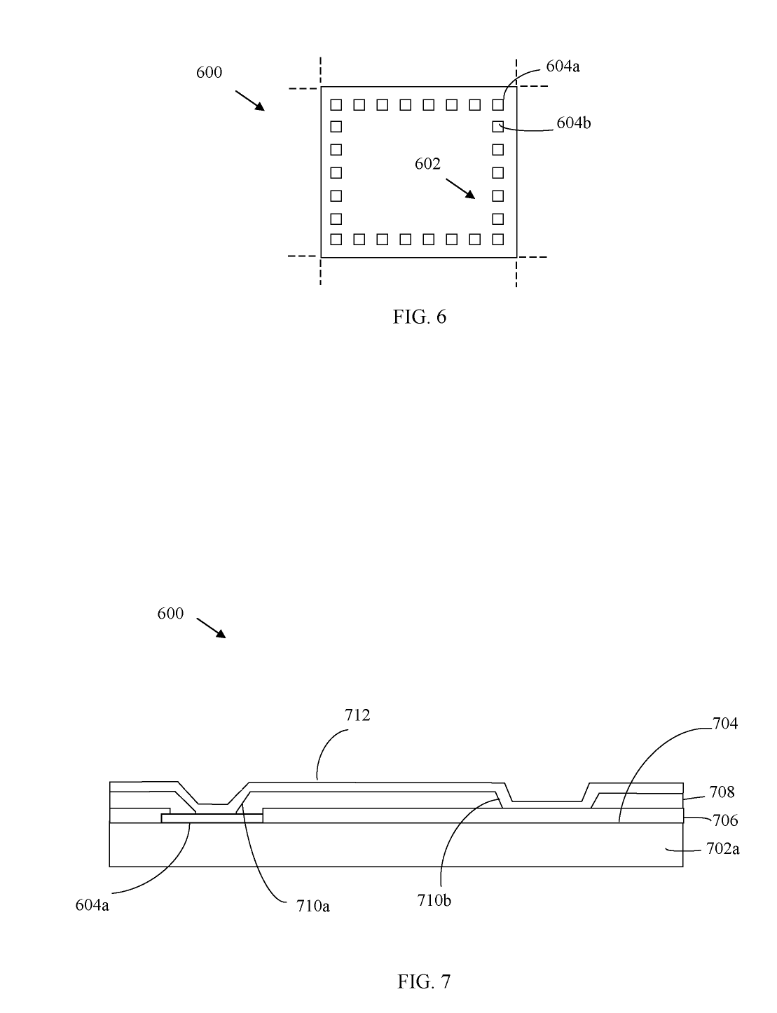

Flowchart 500 begins with step 502. In step 502, the wafer having the plurality of integrated circuit regions is received, each integrated circuit region having a plurality of accessible peripherally positioned on-chip terminals. For instance, FIG. 6 shows a bottom view of an integrated circuit region 600 of a wafer, such as wafer 200 shown in FIG. 2. As shown in FIG. 6, integrated circuit region 600 includes a ring 602 of terminals 604 (terminals 604a and 604b are individually indicated in FIG. 6). Terminals 604 are arranged in ring 602 on the bottom surface (e.g., surface 202) of integrated circuit region 600 adjacent to a peripheral circumferential edge of integrated circuit region 600. An integrated circuit region can include one or more of such rings 602. Terminals 604 may be arranged in-line along each edge, as shown in FIG. 6, may be staggered along each edge, or may have other arrangement. Terminals 604 may be input, output, test, power, ground, etc., pads for an integrated circuit chip/die fabricated in, and defined by integrated circuit region 600.

In step 504, a first polymer layer is formed on the wafer over the plurality of integrated circuits regions. For example, FIG. 7 shows a cross-sectional view of a portion of integrated circuit region 600. As shown in FIG. 7, the portion of integrated circuit region 600 shown includes a chip portion 702a, a terminal 604a on a top surface 704 of chip portion 702a, and a passivation layer 706 that covers the remainder of top surface 704 of chip portion 702a. A first polymer layer 708 is formed on the wafer over integrated circuit region 600 (and other integrated circuit regions on the wafer), covering terminal 604a and passivation layer 706.

In step 506, a plurality of first vias is formed through the first polymer layer. For example, as shown in FIG. 7, a first via 710a is formed through first polymer layer 708. First via 710a provides access to terminal 604a. Similarly to first via 710a, a plurality of vias is formed through first polymer layer 708, each providing access to a respective terminal 604 of integrated circuit region 600. Furthermore, a second via 710b is formed through polymer layer 708. Second via 710b exposes a portion of passivation layer 706.

In step 508, a metal layer is formed on the first polymer layer. For example, as shown in FIG. 7, a metal layer 712 is formed on first polymer layer 708. Metal layer 712 is typically formed on polymer layer 708 using a sputtering or electroplating process.

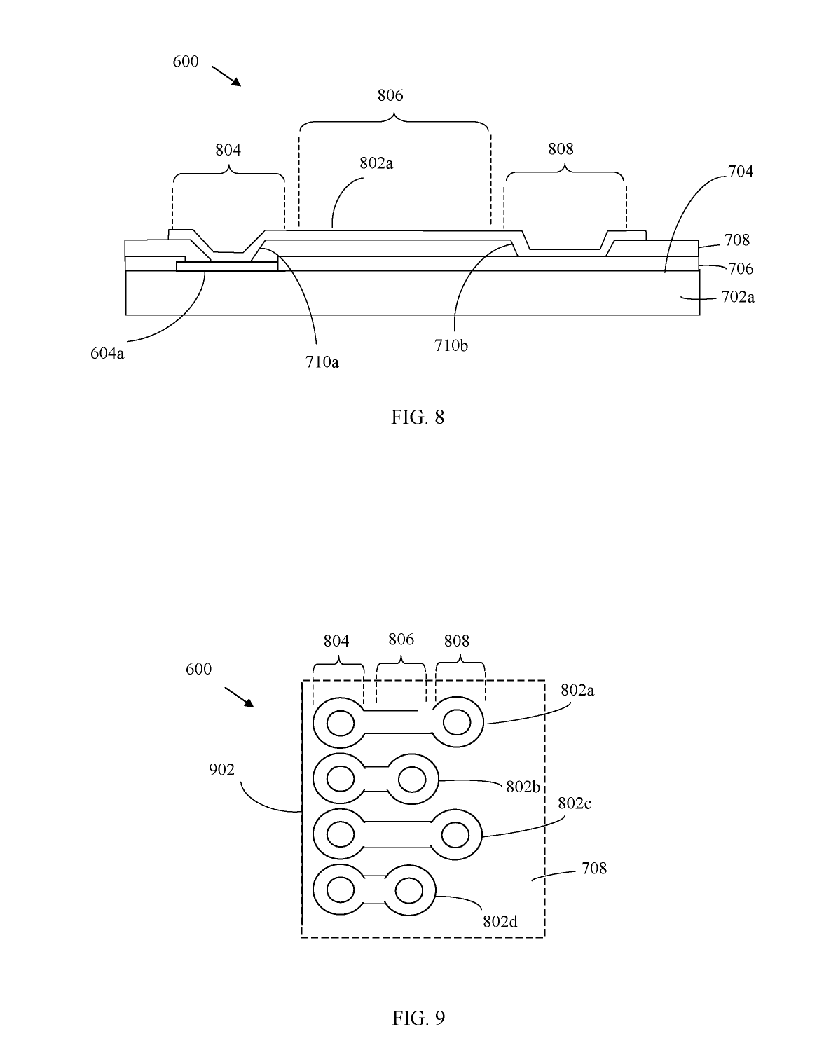

In step 510, a plurality of redistribution layers is formed in the metal layer, each redistribution layer having a first portion in contact with a respective on-chip terminal though a respective first via, a second portion that extends over the first polymer layer, and a third portion. For example, FIG. 8 shows a cross-sectional view of integrated circuit region 600 with further processing as compared to integrated circuit region 600 shown in FIG. 7. As shown in FIG. 8, a redistribution layer 802a is formed in metal layer 712. A plurality of redistribution layers 802 may be formed in integrated circuit region 600. For example, a photolithography or other etching process may be used to form redistribution layers 802 in metal layer 712 by etching away a portion of metal layer 712.

As shown in FIG. 8, a first portion 804 of redistribution layer 802a is in contact with terminal 604a through first via 710a, a second portion 806 of redistribution layer 802 extends (e.g., laterally) over first polymer layer 708, and a third portion 808 of redistribution layer 802 fills second via 710b. Second portion 806 of redistribution layer 802 is connected between first portion 804 and third portion 808.

For instance, FIG. 9 shows a view of a surface of a portion of integrated circuit region 600 at a left edge 902 of integrated circuit region 600. As shown in FIG. 9, four redistribution layers 802a-802d are formed on first polymer layer 708, each redistribution layer having a first portion 804, a second portion 806, and a third portion 808. The first portions 804 of redistribution layers 802a-802d are in contact with four corresponding terminals (not visible in FIG. 8) through four corresponding first vias (not visible in FIG. 8). The second portions 806 of redistribution layers 802a-802d extend over first polymer layer 708 from first portions 804 (e.g., in the rightward direction in FIG. 8). The third portions 808 fill respective second vias 710 (not visible in FIG. 9) in first polymer layer 708.

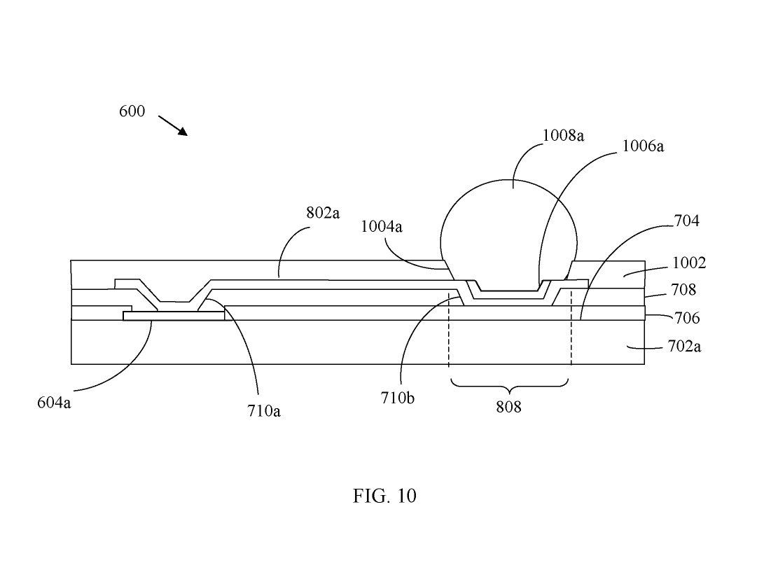

In step 512, a second polymer layer is formed over the first polymer layer and plurality of redistribution layers. For example, FIG. 10 shows a cross-sectional view of integrated circuit region 600 with further processing as compared to integrated circuit region 600 shown in FIG. 8. As shown in FIG. 10, a second polymer layer 1002 is formed on the wafer over integrated circuit region 600 (and other integrated circuit regions on the wafer), covering first polymer layer 708 and redistribution layer 802a.

In step 514, a plurality of second vias is formed through the second polymer layer to provide access to the third portion of each of the plurality of redistribution layers. For example, as shown in FIG. 7, a second via 1004a is formed through second polymer layer 718 to provide access to third portion 808 of redistribution layer 802a. In this manner, a plurality of second vias 1004 are formed through second polymer layer 718, each providing access to a respective third portion 808 of a redistribution layer 802.

In step 516, a plurality of under bump metallization layers is formed on the plurality of redistribution layers, each under bump metallization layer being in contact with the third portion of a respective redistribution layer though a respective second via. For example, as shown in FIG. 10, an under bump metallization layer 1006a is in contact with third portion 808 of redistribution layer 802a through second via 1004a. In this manner, a plurality of under bump metallization layers 1006 may be formed in contact with respective redistribution layers 802 through respective second vias 1004.

Under bump metallization (UBM) layers 1006 are typically one or more metal layers formed (e.g., metal deposition—plating, sputtering, etc.) to provide a robust interface between redistribution layers 802 and a package interconnect mechanism (such as a bump interconnect, such as described in step 518). A UBM layer serves as a solderable layer for a solder package interconnect mechanism. Furthermore, a UBM provides protection for underlying metal or circuitry from chemical/thermal/electrical interactions between the various metals/alloys used for the package interconnect mechanism. In an embodiment, UBM layers 1006 are formed similarly to standard via plating.

In step 518, a plurality of bump interconnects is formed on the plurality of under bump metallization layers. For example, as shown in FIG. 10, a bump interconnect 1008a is formed on under bump metallization layer 1006a. In this manner, a plurality of bump interconnects 1008 may be formed in contact with respective under bump metallization layers 1006. Bump interconnects 1008 may be solder balls, for instance.

In this manner, an electrical connection is formed from each terminal 604 to a respective bump interconnect 1008 (i.e., through a respective redistribution layer 802 and under bump metallization layer 1006). As just described with respect to flowchart 500, multiple polymer layers (e.g., layers 708 and 1002) may be used to support the electrical connection. In many cases, single or multiple polymer material layers are deposited on the wafer below, above, or between the various applied RDL or UBM metal layers. The polymer layers serve multiple purposes. For example, they provide electrical isolation between the different circuitry/metal layers including between redistribution layers 802 and under bump metallization layers 1006 and the circuitry within the chip (chip portion 702a). The polymer layers further provide a layer between the package-to-system interconnect and the chip that can serve as a mechanical buffer to protect the interconnect from stresses that may result due to mismatches in material behavior of the various materials in the package and system (chip, PCB, solder, etc.)

However, this front-end approach described with respect to flowchart 500 has disadvantages. For example, two polymer layers are needed (e.g., layers 708 and 1002), as well as deposition of redistribution layers 802, which require many process steps and additional materials, adding cost. As described above, to form redistribution layers 802, metal layer 712 is deposited using a sputtering, electroplating, or other similar process, which typically are expensive and time consuming. Metal layer 712 is subsequently patterned according to a photolithography process, or other etching process, which typically requires multiple expensive masks used to define the redistribution layers.

Example embodiments of the present invention are described in the following section that overcome disadvantages of the front-end processing approach described above.

### Example Embodiments

The example embodiments described herein are provided for illustrative purposes, and are not limiting. The examples described herein may be adapted to a variety of types of integrated circuit packages. Further structural and operational embodiments, including modifications/alterations, will become apparent to persons skilled in the relevant art(s) from the teachings herein.

According to an embodiment, redistribution layers, also referred to as “routing interconnects,” that connect terminals of a die to bump interconnects, are formed by application of an ink material. For instance, the ink material may be applied by an ink jet printer. Such an embodiment provides for routing interconnects using a less expensive fabrication process that allows for fewer manufacturing process steps than in the fabrication processes described above for routing interconnects formed using sputtering, electroplating, and other similar processes. Furthermore, expensive masks are not required to print routing interconnects. Such a fabrication process may be conducted more rapidly, such as in terms of hours, rather than in terms of days, which is typically required by the process described above with respect to flowchart 500.

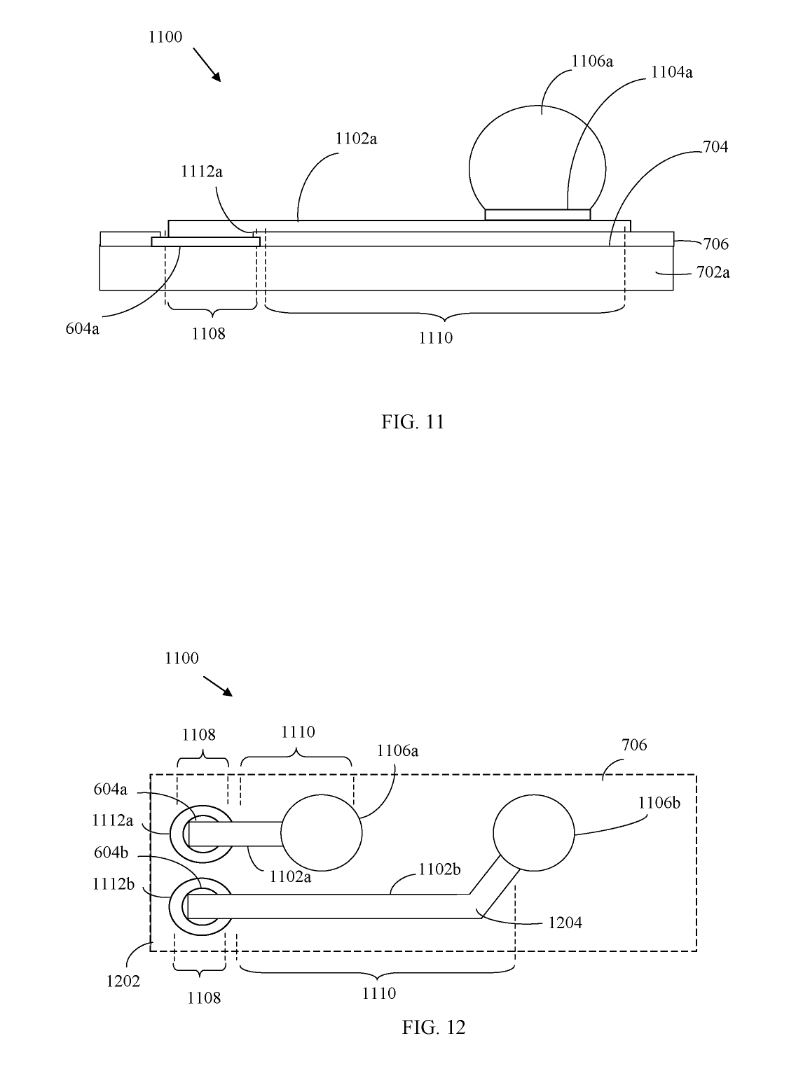

For instance, FIG. 11 shows a cross-sectional view of an integrated circuit region 1100, according to an example embodiment of the present invention. Integrated circuit region 1100 may be an integrated circuit region of wafer 200, for example. In FIG. 11, the portion of integrated circuit region 1100 shown includes chip portion 702a, terminal 604a on top surface 704 of chip portion 702a, passivation layer 706, a printed routing interconnect 1102a, a solderable material 1104a on printed routing interconnect 1102a, and a bump interconnect 1106a on solderable material 1104a. These elements of integrated circuit region 1100 are described below.

As shown in FIG. 11, passivation layer 706 has an opening 1112a. Opening 1112a provides access to terminal 604a through passivation layer 706. Printed routing interconnect 1102a has a first portion 1108 and a second portion 1110. First portion 1108 is in contact with terminal 604a, and second portion 1110 extends over passivation layer 706. Printed routing interconnect 1102a is printed on integrated circuit region 1100 in the form of ink. The ink may be any type of electrically conductive ink that may be printed, including an ink that includes an electrically conductive material, such as a metal or combination of metals. For instance, the ink may be a metal paste that may include silver, copper, platinum, aluminum, gold, nickel, tin, lead, palladium, and/or other metal and/or metal alloy. For example, the ink may be a “nanopaste” that includes nano-scale particles of silver, copper, platinum, aluminum, gold, nickel, tin, lead, palladium, and/or other metal and/or metal alloy, that is dispersed in a carrier (e.g., a solvent). In embodiments, the nanopaste is configured to have a viscosity and/or surface tension suitable for ink jet printing onto a wafer substrate, and is configured to adhere to a wafer substrate.

For instance, in an embodiment, the nanopaste may include nano-scale silver (and/or other metal) particles uniformly dispersed in a polar or non-polar solvent to form a high solid content/high viscosity ink. Suitable carriers may be selected, depending on the particular nanopaste and the desired application, and may include organic carriers, aqueous carriers and mixtures of organic and aqueous liquids. In another embodiment, the nanopaste is an inorganic nanopaste including inorganic nanoparticles in a substantially aqueous carrier. In an embodiment, the carrier may be composed of water or mixtures of water with water-miscible organic solvents such as suitable alcohols. Suitable examples of the nanopastes described herein include a silver/palladium sol having a metallic particle average diameter of 11.1 nm, which is supplied in a 5 w/w % solution in water by Advanced Nano Products (ANP) Co., Chungcheongbukdo, Korea. Another example is a silver sol having a metallic particle average diameter of 11.0 nm, which is supplied in a 5 w/w % solution in water by ANP Co.

As shown in FIG. 11, solderable material 1104a is formed on a portion of second portion 1110 of routing interconnect 1102a. In an embodiment, solderable material 1104a may be similar to an under bump metallization (UBM) layer, as described above. The presence of solderable material 1104a is optional. Solderable material 1104a, when present, is configured to improve an adhesion between bump interconnect 1106a and routing interconnect 1102a. For instance, in an embodiment, bump interconnect 1106a may be a solder that does not adhere well to the material of routing interconnect 1102a, which may not be solderable in an embodiment. However, the material of solderable material 1102a is solderable, and bump interconnect 1106a can adhere to solderable material 1102a. Thus, solderable material 1102a may be applied as an outermost solderable layer to routing interconnect 1102a in region 1110 so that bump interconnect 1106a can be attached to routing interconnect 1102a through solderable material 1102a. Furthermore, routing interconnect 1102a, which may not be solderable in an embodiment, prevents solder of bump interconnect 1106a from wetting toward terminal 604a and potentially damaging the integrated circuit. In alternative embodiment, when solderable material 1104a is not present, bump interconnect 1106a may be formed directly on routing interconnect 1102a in second portion 1110. In such an embodiment, routing interconnect 1102a may be made from a material that is solderable.

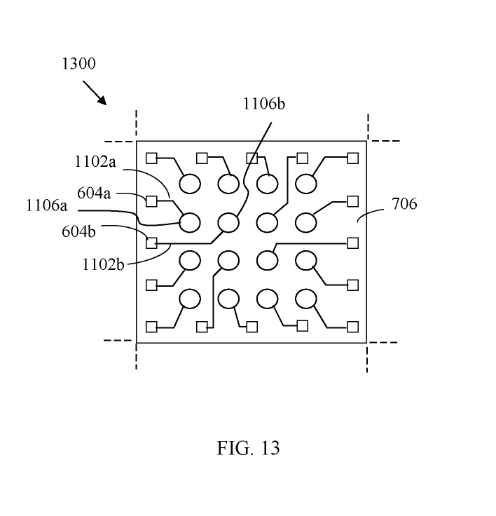

FIG. 12 shows a surface view of the portion of integrated circuit region 1100 shown in FIG. 11. In FIG. 12, first and second routing interconnects 1102a and 1102b are formed on passivation layer 706, with each of routing interconnects 1102a and 1102b having a first portion 1108 and a second portion 1110. First portions 1108 of routing interconnects 1102a and 1102b are in contact with a corresponding one of terminals 604a and 604b through a corresponding one of openings 1112a and 1112b in passivation layer 706. In the example of FIG. 12, terminals 604a and 604b are located adjacent to an edge 1202 of integrated circuit region 1100 (e.g., in an inline terminal configuration, as shown in FIG. 6). Second portions 1110 of routing interconnects 1102a and 1102b extend over passivation layer 706 from first portions 1108 (e.g., in the rightward direction in FIG. 12).

Note that first portions 1108 of routing interconnects 1102 may have various shapes. For example, first portion 1108 of routing interconnects 1110a and 1110b shown in FIG. 12 are rectangular shaped portions. Alternatively, first portions 1108 may be shaped similar to a standard via plating, may fill openings 1112 partially or entirely, and may include a via pad surrounding opening 1112.

Furthermore, second portions 1110 of routing interconnects 1102 can have various shapes. For example, as shown in FIG. 12, second portions 1110 may be rectangular shaped, similar to standard trace routing. Alternatively, second portions 1110 may have other shapes. Furthermore, second portion 1110 may include one or more bends and/or curves to route between a corresponding first portion 1108 and a region on passivation layer 706 at which a bump interconnect 1106 is desired to be located. For example, as shown in FIG. 12, second portion 1110 of routing interconnect 1102b includes a bend 1204. Such shaping of routing interconnects 1102 enables pluralities of bump interconnects 1106 to be positioned in any arrangement in an integrated circuit region, including in an array of bump interconnects 1106.

For instance, FIG. 13 shows an integrated circuit region 1300, according to an example embodiment of the present invention. In FIG. 13, terminals 604 are arranged in an inline manner along each edge of integrated circuit region 1300, to form a perimeter ring of terminals 604. Five terminals 604 are shown along each edge of integrated circuit region 1300 in FIG. 13, for a total of sixteen terminals 604, for illustrative purposes. Furthermore, a two-dimensional array of bump interconnects 1106, arranged in rows and columns, is present on integrated circuit region 1300 within the perimeter ring formed by terminals 604. A four-by-four array of bump interconnects 1106 is shown in FIG. 13, for illustrative purposes. Furthermore, a plurality of routing interconnects 1102 are present in integrated circuit region 1300 (sixteen routing interconnects 1102 are shown in FIG. 13). Each routing interconnect 1102 is routed between a corresponding terminal 604 and bump interconnect 1106, to form an electrical connection between them. Routing interconnects 1102 are routed as needed, including one or more bends, to form a path between the corresponding terminal 604 and bump interconnect 1106.

In embodiments, any number of terminals 604, bump interconnects 1106, and corresponding routing interconnects 1102 may be present in an integrated circuit region, as desired for a particular application, including hundreds or even thousands of terminals 604, bump interconnects 1106, and corresponding routing interconnects 1102. Each terminal 604 may be connected to one or more bump interconnects 1106 by routing interconnects 1102, and each bump interconnect 1106 may be connected to one or more terminals 604 by routing interconnects 1102. Furthermore, terminals 604 may be formed in any arrangement, including in a straight inline arrangement (as in FIG. 13) or a staggered arrangement (e.g., a zigzag formation along each edge), and may be formed in any number of concentric rings along the perimeter of an integrated circuit region. Bump interconnects 1106 may be formed in any arrangement in an integrated circuit region, including in a regular array (as in FIG. 13), in a staggered array, or any other arrangement.

In the example of FIG. 13, integrated circuit 1300 may be a legacy die design, where terminals 604 were designed for wire bond attachment. According to embodiments of the present invention, by forming routing interconnects 1102 and bump interconnects 1106, integrated circuit 1300 may be converted from a wire bond application to a flip chip-type application. In a flip chip application, after being singulated from a wafer, integrated circuit region 1300 may be mounted to a circuit board as a wafer-level integrated circuit die using bump interconnects 1106. The array of bump interconnects 1106 attach (e.g., by solder reflow or other mechanism) to a corresponding array of contact pads on a surface of the circuit board.

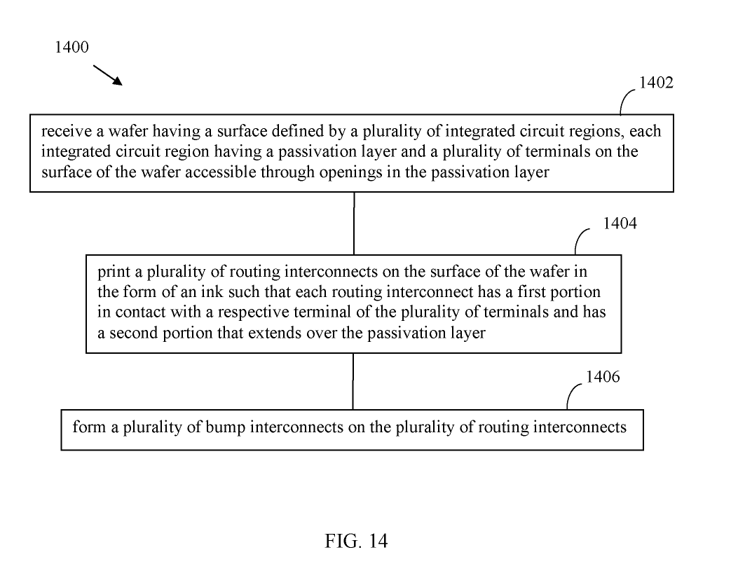

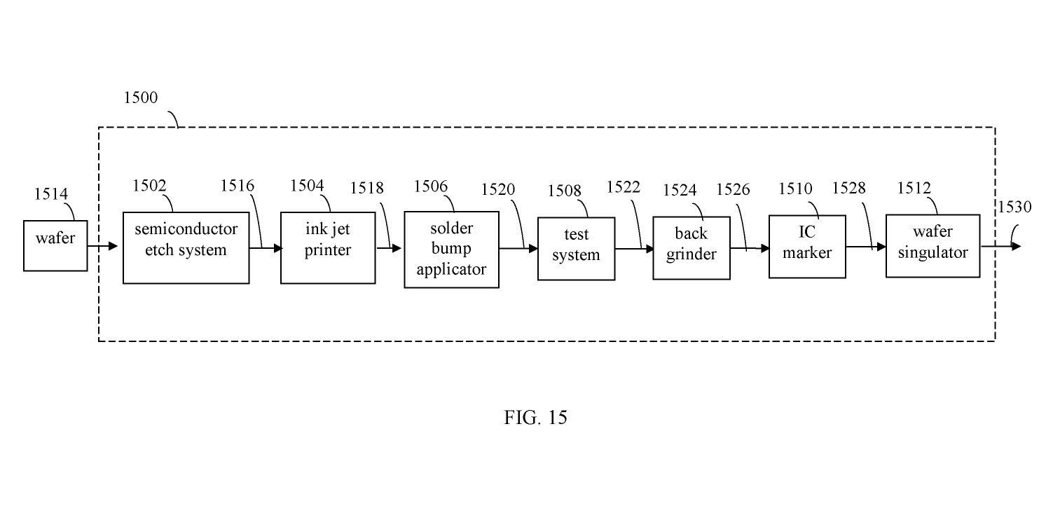

Wafer-level integrated circuit packages that include routing interconnects 1102 may be formed in a variety of ways. For example, flowchart 100 shown in FIG. 1, and described above, may be adapted to forming such packages. For instance, FIG. 14 shows a flowchart 1400 for front-end processing of integrated circuit packages, according to an embodiment of the present invention. Flowchart 1400 may be performed during step 104 of flowchart 100, for example. Flowcharts 100 and 1400 are described below with respect to an integrated circuit package fabrication system 1500 shown in FIG. 15, for illustrative purposes. As shown in FIG. 15, system 1500 includes a semiconductor etch system 1502, an ink jet printer 1504, a solder bump applicator 1506, a test system 1508, a back grinder 1524, an IC marker 1510, and a wafer singulator 1512. Other structural and operational embodiments will be apparent to persons skilled in the relevant art(s) based on the discussion provided herein.

As shown in FIG. 15, a wafer 1514 is received by semiconductor etch system 1502 of system 1500. In an embodiment, semiconductor etch system 1502 may be used to perform step 102 of flowchart 100, as described above. Wafer 200 shown in FIG. 2 and described above is an example of wafer 1514 shown in FIG. 15. Semiconductor etch system 1502 is configured to fabricate integrated circuits on a surface of wafer 1514 to define a plurality of integrated circuit regions, such as integrated circuit region 600 shown in FIG. 6. Semiconductor etch system 1502 may include any type of integrated circuit fabrication functionality, including a photolithography system. Semiconductor etch system 1502 outputs a wafer with integrated circuit regions 1516.

Referring to flowchart 1400 (FIG. 14), in step 1402, a wafer having a surface defined by a plurality of integrated circuit regions is received, each integrated circuit region having a passivation layer and a plurality of terminals on the surface of the wafer accessible through openings in the passivation layer. For instance, as shown in FIG. 15, wafer with integrated circuit regions 1516 is received by ink jet printer 1504.

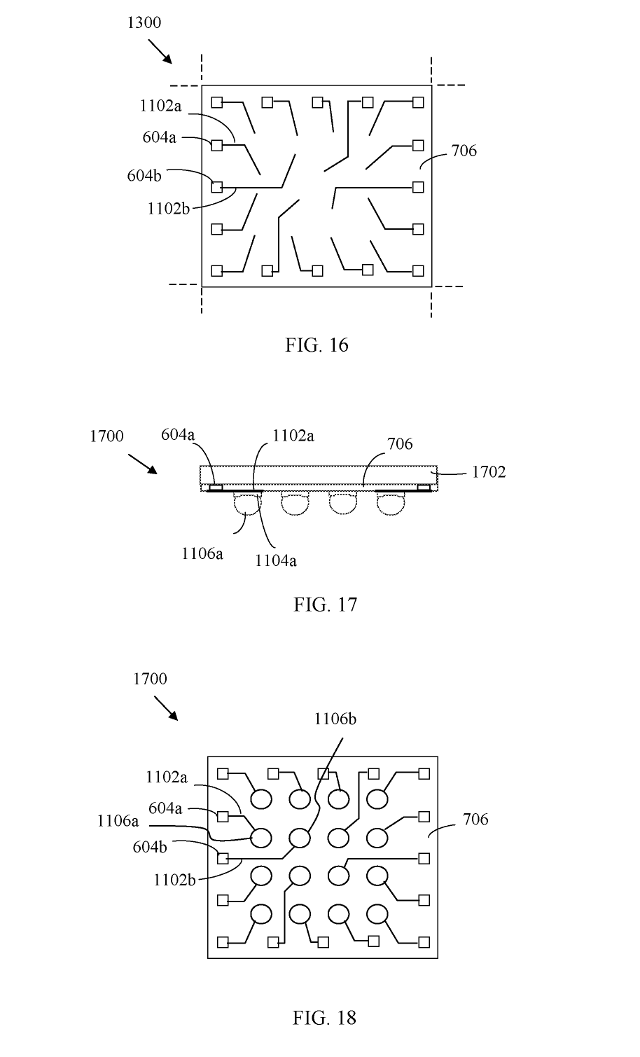

In step 1404, a plurality of routing interconnects is printed on the surface of the wafer in the form of an ink such that each routing interconnect has a first portion in contact with a respective terminal of the plurality of terminals and has a second portion that extends over the passivation layer. In an embodiment, ink jet printer 1504 shown in FIG. 15 prints routing interconnects 1102 on a surface of the wafer received in step 1402. Ink jet printer 1504 may be configured to print a plurality of routing interconnects 1102 in each integrated circuit region, such as integrated circuit region 600 shown in FIG. 6, of the received wafer. For example, FIG. 16 shows integrated circuit region 1300 of FIG. 13 prior to application of bump interconnects 1106. As shown in FIG. 16, a plurality of routing interconnects 1102 are printed on passivation layer 706 of integrated circuit region 1300 (routing interconnects 1102a and 1102b are specifically indicated in FIG. 16).

Ink jet printer 1504 is an ink jet printer configured to print an electrically conductive ink in the form of routing interconnects 1102 on a wafer. Examples of electrically conductive inks include those described elsewhere herein, such as a metal-based ink and/or a nanopaste, or other suitable electrically conductive inks known to persons skilled in the relevant art(s). Ink jet printer 1504 is configured to print electrically conductive inks having a suitable viscosity and/or surface tension, and that are configured to adhere to a wafer substrate. Furthermore, ink jet printer 1504 is configured to print routing interconnects 1102 having a suitable width to enable a suitable pitch for bump interconnects 1106. An example pitch for bump interconnects 1106, in an embodiment, is 200 microns. In example embodiments, routing interconnects 1102 may have a width of 38 microns, with 38 microns spacing between adjacent routing interconnects 1102, a width of 25 microns, with 12 microns spacing between adjacent routing interconnects 1102, or other suitable width and spacing, as would be known to persons skilled in the relevant art(s). In an embodiment, a conventional ink jet printer may be configured to print electrically conductive ink as ink jet printer 1504, by replacing an ink reservoir of the conventional ink jet printer with electrically conductive ink. Furthermore, the ink jet printer may be provided with electronic routing interconnect layout information to configure the ink jet printer to print ink in a particular circuit configuration. Examples of conventionally available ink jet printers that may be adapted to be used as ink jet printer 1504 include ink jet printers manufactured by Hewlett-Packard Co., Palo Alto, Calif.

In an embodiment, ink jet printer 1504 may print a single layer of electrically conductive ink on the wafer to form bump interconnects 1106. In another embodiment, ink jet printer 1504 may print multiple layers of electrically conductive ink on the wafer to form bump interconnects 1106 as stacks of electrically conductive ink. Ink jet printer 1504 may be configured to enable the ink printed on the wafer to cure (e.g., by allowing a suitable amount of time to pass, by applying heat, etc.), if necessary for the particular ink, prior to printing a next layer of ink, and/or prior to outputting the wafer. As shown in FIG. 15, ink jet printer 1504 outputs a wafer with printed routing distribution layers (RDLs) 1518.

In step 1406, a plurality of bump interconnects is formed on the plurality of routing interconnects. In an embodiment, solder bump applicator 1506 is configured to form bump interconnects 1106 on routing interconnects 1102. For example, as shown in FIG. 12, a bump interconnect 1106a is formed on routing interconnect 1102a, and a bump interconnect 1106b is formed on routing interconnect 1102b. In the example of FIG. 13, sixteen bump interconnects 1106 are formed on sixteen routing interconnects 1102.

Bump interconnects 1106 may be formed of any suitable electrically conductive material, including a metal such as a solder or solder alloy, copper, aluminum, gold, silver, nickel, tin, titanium, lead, a combination of metals/alloy, etc. Bump interconnects 1106 may have any size and pitch, as suitable for a particular application. Solder bump applicator 1506 may be configured to form bump interconnects 1106 in any manner, including by sputtering, electroplating, solder paste or ball loading, lithographic processes, etc., as would be known to persons skilled in the relevant art(s). As shown in FIG. 15, solder bump applicator 1506 outputs a wafer with bump interconnects 1520.

In an embodiment, as shown in FIG. 11, prior to forming bump interconnects 1106 on routing interconnects 1102 according to step 1406, solderable material 1104 may be formed on routing interconnects 1102. In such an embodiment, step 1406 may include forming bump interconnects 1106 on solderable material 1104. In an embodiment, solder bump applicator 1506 may be configured to form solderable material 1104 on routing interconnects 1102.

In an embodiment, step 1404 of flowchart 1400 may be performed prior to step 1406. In this manner, routing interconnects 1102 may be printed on the wafer, and bump interconnects 1106 may be formed on routing interconnects 1102. In another embodiment, step 1406 of flowchart 1400 may be performed prior to step 1404. In this manner, bump interconnects 1106 may be formed on the wafer, and routing interconnects 1102 may be printed on the wafer, including printing a portion of routing interconnects 1102 on ball interconnects 1106.

As shown in FIG. 15, wafer with bump interconnects 1520 is received by test system 1508. In an embodiment, test system 1508 may perform step 106 of flowchart 100 (FIG. 1), as described above. Test system 1508 may be configured to test the integrated circuits, routing interconnects 1102, and/or bump interconnects 1106 on a surface of the received wafer in any manner, as would be known to persons skilled in the relevant art(s). Test system 1508 outputs a tested wafer 1522.

In an embodiment, back grinder 1524, IC marker 1510, and wafer singulator 1512 may be configured to perform step 108 of flowchart 100 shown in FIG. 1. For example, back grinder 1524 may be configured to perform step 402, IC marker 1510 may be configured to perform step 404, and wafer singulator 1512 may be configured to perform step 406 of flowchart 400 shown in FIG. 4. As shown in FIG. 15, back grinder 1524 receives tested wafer 1522, and outputs a thinned wafer 1526. Back grinder 1524 may include any mechanism for thinning a received wafer, such as a wafer grinder, as would be known to persons skilled in the relevant art(s).

As shown in FIG. 15, IC marker 1510 receives thinned wafer 1526, and outputs a marked wafer 1528. IC marker 1510 may include any mechanism for marking integrated circuit regions in a wafer, as would be known to persons skilled in the relevant art(s).

Wafer singulator 1512 receives marked wafer 1528, and outputs a plurality of wafer-level integrated circuit packages 1530. Wafer singulator 1512 may include any mechanism for singulating a wafer, such as a saw, laser, and/or other mechanism, as would be known to persons skilled in the relevant art(s).

FIGS. 17 and 18 show side cross-sectional and bottom views of an example wafer-level integrated circuit package 1700 singulated from a wafer, such as wafer 1514 shown in FIG. 15, according to an example embodiment of the present invention. In the example of FIGS. 17 and 18, package 1700 is a singulated version of integrated circuit region 1300 shown in FIG. 13.

As shown in FIG. 17, package 1700 includes an integrated circuit die 1702, passivation layer 706, a plurality of terminals 604, a plurality of routing interconnects 1102, a plurality of solderable material 1104, and a plurality of bump interconnects 1106. Die 1702 is a portion of the wafer that includes integrated circuit region 1300, and is formed by singulating integrated circuit region 1300 from the wafer. As shown in FIGS. 17 and 18, die 1702 has a plurality of terminals 604 on a surface. Passivation layer 706 is formed on the surface of die 1702. Routing interconnects 1102 each have a first portion in contact with a respective terminal 604, and a second portion extending over passivation layer 706. As described above, routing interconnects 702 are formed of a solidified ink, printed by an ink jet printer (e.g., ink jet printer 1504 shown in FIG. 15). Each bump interconnect 1106 is coupled to the second portion of a respective routing interconnect 1102. Any number of packages 1700 may be singulated from a particular wafer, depending on the size of the wafer, and size of the integrated circuit regions in the wafer that correspond to package 1700.

### Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A method for forming integrated circuit (IC) packages, comprising:
receiving a wafer having a surface defined by a plurality of integrated circuit regions, each integrated circuit region having a passivation layer and a plurality of terminals on the surface of the wafer accessible through openings in the passivation layer;
printing a plurality of routing interconnects on the surface of the wafer in the form of an ink such that each routing interconnect has a first portion in contact with a respective terminal of the plurality of terminals and has a second portion that extends over the passivation layer; and
forming a plurality of bump interconnects on the plurality of routing interconnects such that each bump interconnect of the plurality of bump interconnects is formed on the second portion of a respective routing interconnect of the plurality of routing interconnects.

2. The method of claim 1, wherein said printing comprises:
printing a plurality of layers of ink to form the plurality of routing interconnects.

3. The method of claim 1, wherein forming a plurality of routing interconnects comprises:
applying a solderable material to each routing interconnect in a region designated for a connection of a bump interconnect; and
forming each bump interconnect of the plurality of bump interconnects on the solderable material of a respective routing interconnect of the plurality of routing interconnects.

4. The method of claim 1, wherein the ink includes a metal paste, wherein said printing comprises:
printing the metal paste on the surface of the wafer to form the plurality of routing interconnects.

5. The method of claim 4, wherein the metal paste is a nanopaste, wherein said printing comprises:
printing the nanopaste on the surface of the wafer to form the plurality of routing interconnects.

6. The method of claim 1, wherein said printing comprises:
ink jet printing the plurality of routing interconnects on the surface of the wafer.

7. The method of claim 1, further comprising:
singulating the wafer to form a plurality of integrated circuit packages that each include at least one integrated circuit region of the plurality of integrated circuit regions.

8. An integrated circuit (IC) package, comprising:
an integrated circuit die having a plurality of terminals on a surface of the integrated circuit die;
a passivation layer on the surface of the integrated circuit die having a plurality of openings that provide access to the plurality of terminals;
a plurality of routing interconnects each having a first portion and a second portion, the first portion of each routing interconnect being in contact with a respective terminal of the plurality of terminals though a respective opening in the passivation layer and the second portion of each routing interconnect extending over the passivation layer, and each routing interconnect comprising a solidified ink; and
a plurality of bump interconnects, wherein each bump interconnect of the plurality of bump interconnects is coupled to the second portion of a respective routing interconnect of the plurality of routing interconnects.

9. The IC package of claim 8, wherein each routing interconnect comprises a stack of layers of solidified ink.

10. The IC package of claim 8, further comprising:
a solderable material on each routing interconnect;
wherein each bump interconnect of the plurality of bump interconnects is coupled to a respective routing interconnect of the plurality of routing interconnects by the solderable material.

11. The IC package of claim 8, wherein the ink includes a metal paste.

12. The IC package of claim 11, wherein the metal paste is a nanopaste.

13. The IC package of claim 11, wherein the metal paste includes at least one of silver or copper.

14. The IC package of claim 8, wherein the plurality of bump interconnects are formed in an array of rows and columns of bump interconnects on the surface of the integrated circuit die.

15. A system for processing a wafer to form integrated circuit (IC) packages, comprising:
an ink jet printer configured to print a plurality of routing interconnects on the surface of a wafer in the form of an ink, the wafer having a surface defined by a plurality of integrated circuit regions, each integrated circuit region having a passivation layer and a plurality of terminals on the surface of the wafer accessible through openings in the passivation layer;
wherein the ink jet printer is configured to print the plurality of routing interconnects such that each routing interconnect has a first portion in contact with a respective terminal of the plurality of terminals and has a second portion that extends over the passivation layer.

16. The system of claim 15, further comprising:
a solder bump applicator configured to form a plurality of bump interconnects on the plurality of routing interconnects such that each bump interconnect of the plurality of bump interconnects is formed on the second portion of a respective routing interconnect of the plurality of routing interconnects.

17. The system of claim 15, wherein the ink jet printer is configured to print using a metal paste as the ink.

18. The system of claim 17, wherein the ink jet printer is configured to print using a nanopaste as the metal paste.

19. The system of claim 17, wherein the metal paste includes at least one of silver or copper.
